(19) United States
(12) Patent Application Publication
(10) Pub. No.: US 2023/0065412 A1
(43) Pub. Date: Mar. 2, 2023

(54) DIVIDING METHOD OF SUBSTRATE

(71) Applicant: DISCO CORPORATION, Tokyo (JP)

(72) Inventors: Jaeyoung LEE, Tokyo (JP); Shuzo MITANI, Tokyo (JP); Takayuki KITANO, Tokyo (JP)

(21) Appl. No.: 17/818,071

(22) Filed: Aug. 8, 2022

(30) Foreign Application Priority Data
Aug. 27, 2021 (JP) 2021-138929

(51) Int. Cl. H01L 21/463; H01L 21/428

(52) U.S. Cl. CPC H01L 21/463; H01L 21/428

(57) ABSTRACT

A dividing method of a substrate includes a close contact step of bringing an expanding tape into close contact with a substrate after execution of a modified layer forming step and before execution of a chip interval expansion step. Therefore, when the expanding tape is expanded in the chip interval expansion step, it is possible to favorably form plural chips with use of modified layers as the origin and to favorably widen the interval between the plural chips.

### BACKGROUND OF THE INVENTION

### Field of the Invention

The present invention relates to a dividing method of a substrate.

### Description of the Related Art

As a related art, as disclosed in Japanese Patent Laid-open No. 2012-109338, as a method for dividing a substrate inside which modified layers to become origin of dividing are formed and that is stuck to an expanding tape, a method is known in which, by expanding the expanding tape, the substrate is divided into plural chips with use of the modified layers as the origins and the chip interval is widened.

### SUMMARY OF THE INVENTION

However, when a degree of bonding between an expanding tape and the substrate is weak in the above-described dividing method, there is a fear that the substrate is not expanded together when the expanding tape is expanded and a region that is not divided into chips is caused in the substrate.

Furthermore, in some cases, a process of widening the interval of chips needs to be executed after an expanding tape is stuck to a back surface side of a substrate and irradiation with a laser beam is executed from the back surface side through the expanding tape to form modified layers that become the origin of dividing in the substrate and then the expanding tape is expanded to divide the substrate into the chips along the origin of dividing.

However, in the expansion process, it takes a long time from the sticking of the expanding tape to the substrate until the expansion of the expanding tape. Thus, in some cases, the degree of bonding between the expanding tape and the substrate lowers and it becomes difficult to favorably widen the chip interval at the time of the expansion of the expanding tape.

Thus, an object of the present invention is to provide a dividing method of a substrate by which the substrate can be favorably divided into plural chips and the interval between the plural chips can be favorably widened.

In accordance with an aspect of the present invention, there is provided a dividing method of a substrate for dividing the substrate along planned dividing lines. The dividing method includes an expanding tape sticking step of sticking an expanding tape to a back surface of the substrate and a modified layer forming step of executing irradiation with a laser beam with a wavelength having transmissibility with respect to the substrate along the planned dividing lines in a state in which a focal point is positioned inside the substrate, to form modified layers that become an origin of dividing inside the substrate, after execution of the expanding tape sticking step. The dividing method includes also a close contact step of bringing the expanding tape into close contact with the substrate after execution of the modified layer forming step and a chip interval expansion step of expanding the expanding tape to divide the substrate into a plurality of chips with use of the modified layers as the origins and widen an interval formed between the plurality of chips after execution of the close contact step.

Preferably, in the close contact step, in a state in which either one of the substrate and the expanding tape is supported by a support table, a roller is rolled against another.

Preferably, a glue layer is stacked on the expanding tape and the glue layer is divided along the modified layers in the chip interval expansion step.

In the dividing method of a substrate according to the present invention, the close contact step of bringing the expanding tape into close contact with the substrate is executed after execution of the modified layer forming step and before execution of the chip interval expansion step. Thus, when the expanding tape is expanded in the chip interval expansion step, the substrate is pulled together with the expanding tape and the substrate can be favorably divided into the plural chips with use of the modified layers as the origin. In addition, the interval between the plural chips can be favorably widened.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating a frame unit;

FIG. 2 is a sectional view illustrating an expanding tape sticking step;

FIG. 3 is a sectional view illustrating a modified layer forming step;

FIG. 4 is a sectional view illustrating a close contact step;

FIG. 5 is a sectional view illustrating a chip interval expansion step;

FIG. 6 is a sectional view illustrating the chip interval expansion step;

FIG. 7 is a sectional view illustrating another modified layer forming step;

FIG. 8 is a sectional view illustrating another close contact step; and

FIG. 9 is a partially sectional side view illustrating a grinding step.

### DETAILED DESCRIPTION OF THE PREFERRED EMBODIMENTS

### First Embodiment

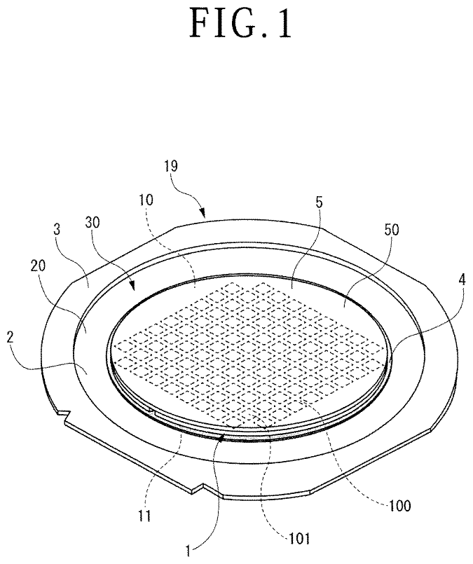

A circular plate-shaped substrate 1 illustrated in FIG. 1 is, for example, a semiconductor wafer with a circular plate shape and a material thereof is silicon, sapphire, gallium arsenide, silicon carbide (SiC), or the like. Planned dividing lines 100 in a lattice manner are formed in a front surface 10 of the substrate 1 and devices 101 are formed in regions marked out by the planned dividing lines 100. A protective sheet 5 that protects the devices 101 may be stuck to the front surface 10 of the substrate 1.

In the present embodiment, the substrate 1 is treated in the state of a frame unit 19 including an annular frame 3 and an expanding tape 2 as illustrated in FIG. 1. A dividing method of a substrate according to the present embodiment will be described below. This method includes forming the frame unit 19 and dividing the substrate 1 in the formed frame unit 19 along the planned dividing lines 100.

(Expanding Tape Sticking Step)

In this step, first, the substrate 1 is positioned inside a circular opening 30 of the annular frame 3. Then, from the side of a back surface 11 of the substrate 1, the expanding tape 2 is stuck to the back surface 11 of the substrate 1 and the annular frame 3. Thereby, the frame unit 19 is formed.

A single-side surface of the expanding tape 2 is an adhesive surface 20 having adhesiveness. Moreover, a glue layer 4 is stacked on a central part of the adhesive surface 20 of the expanding tape 2. The glue layer 4 is a die attach film (DAF), for example.

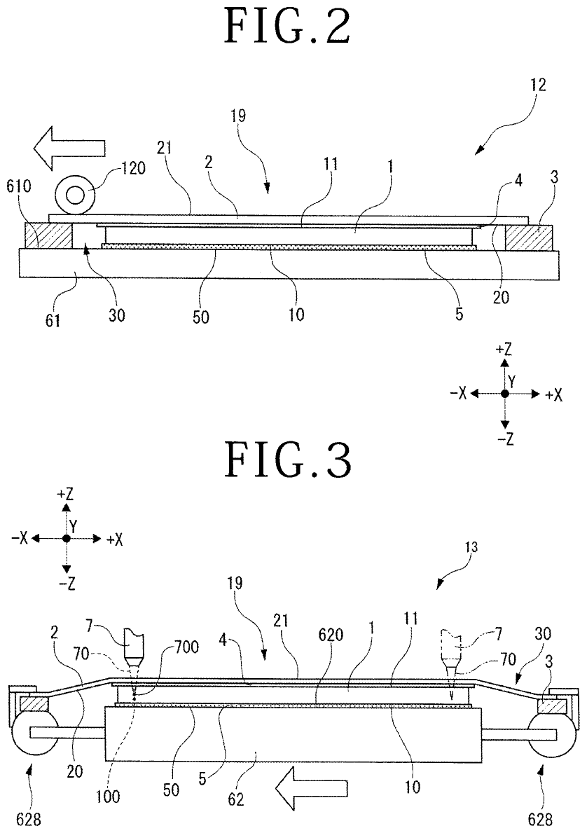

The sticking of the expanding tape 2 to the back surface 11 of the substrate 1 and the annular frame 3 is executed by an expanding tape sticking apparatus 12 illustrated in FIG. 2. The expanding tape sticking apparatus 12 includes a first support table 61 and a roller 120. The first support table 61 has a support surface 610 for supporting the protective sheet 5 stuck to the front surface 10 of the substrate 1 and the annular frame 3. The roller 120 is a cylindrical component that extends in a direction toward the far side of the plane of paper (Y-axis direction). A rolling mechanism that is not illustrated in the diagram is connected to the roller 120 and the roller 120 rolls in an X-axis direction by this rolling mechanism. The protective sheet 5 may be set on the support surface 610 without being stuck to the substrate 1.

When the expanding tape 2 is stuck to the back surface 11 of the substrate 1 and the annular frame 3 by the expanding tape sticking apparatus 12, first, the annular frame 3 is placed on the support surface 610 of the first support table 61.

Furthermore, the substrate 1 is placed inside the opening 30 of the annular frame 3 on the support surface 610 with the front surface 10 thereof oriented downward. Due to this, the back surface 11 of the substrate 1 is exposed over the first support table 61.

Then, the expanding tape 2 is placed on the annular frame 3 and the back surface 11 of the substrate 1 in such a manner that the adhesive surface 20 is oriented downward and the glue layer 4 overlaps with the back surface 11 of the substrate 1. Thereby, the glue layer 4 of the expanding tape 2 gets contact with the back surface 11 of the substrate 1 and the glue layer 4 is stuck to the back surface 11 of the substrate 1. Moreover, the adhesive surface 20 outside the glue layer 4 in the expanding tape 2 gets contact with the upper surface of the annular frame 3 and the expanding tape 2 is stuck to the annular frame 3.

Next, the roller 120 is positioned to an end part on the +X direction side in a contact surface 21 that is the surface on the opposite side to the adhesive surface 20 in the expanding tape 2 and the roller 120 is rolled in the −X direction. Thereby, the glue layer 4 of the expanding tape 2 is pressed against the back surface 11 of the substrate 1 and the degree of bonding between the glue layer 4 and the back surface 11 of the substrate 1 improves. Furthermore, the adhesive surface 20 of the expanding tape 2 is pressed against the annular frame 3 and the degree of bonding between the adhesive surface 20 and the annular frame 3 improves. In this manner, the frame unit 19 in which the substrate 1, the expanding tape 2, and the annular frame 3 are integrated like that illustrated in FIG. 1 is formed.

The expanding tape 2 may be pressed against the back surface 11 of the substrate 1 and the annular frame 3 by moving the roller 120 in the +X direction relative to the first support table 61 through horizontally moving the first support table 61 in the −X direction in the state in which the roller 120 is positioned to an end part of the contact surface 21 on the −X direction side.

(Modified Layer Forming Step)

In this step, after the execution of the expanding tape sticking step, laser processing on the planned dividing lines 100 of the substrate 1 is executed by a laser processing apparatus 13 illustrated in FIG. 3. Specifically, in this step, irradiation with a laser beam with a wavelength having transmissibility with respect to the substrate 1 is executed along the planned dividing lines 100 in the state in which the focal point is positioned inside the substrate 1, and modified layers that become the origin of dividing are formed inside the substrate 1.

The laser processing apparatus 13 includes a second support table 62 as illustrated in FIG. 3. The second support table 62 includes a support surface 620 for supporting the frame unit 19.

Four frame fixing units 628 are disposed on lateral sides of the second support table 62 in such a manner as to surround the second support table 62, and two of these frame fixing units 628 are illustrated in FIG. 3. The frame fixing units 628 are clamps that clamp and fix the annular frame 3 from the outer circumferential side.

Furthermore, the second support table 62 is connected to a horizontal movement mechanism that is not illustrated in the diagram. The second support table 62 and the frame fixing units 628 horizontally move integrally by this horizontal movement mechanism. Moreover, the second support table 62 is connected to a rotation mechanism that is not illustrated in the diagram. The second support table 62 and the frame fixing units 628 integrally rotate by this rotation mechanism.

Furthermore, the laser processing apparatus 13 includes an irradiation head 7 that irradiates the substrate 1 of the frame unit 19 supported by the support surface 620 with a laser beam 70 with a wavelength having transmissibility with respect to the substrate 1.

When the laser processing on the planned dividing lines 100 of the substrate 1 is executed, first, the frame unit 19 is removed from the expanding tape sticking apparatus 12 (see FIG. 2) and, as illustrated in FIG. 3, the substrate 1 of the frame unit 19 is placed over the support surface 620 of the second support table 62 in the laser processing apparatus 13 with the protective sheet 5 stuck to the front surface 10 of the substrate 1 oriented downward. Thereby, the second support table 62 supports the substrate 1 with the interposition of the protective sheet 5. At this time, the substrate 1 may be sucked and held by the support surface 620 by actuating a suction source that is connected to the second support table 62 and is not illustrated in the diagram and transmitting a suction force to the support surface 620 of the second support table 62.

Furthermore, by the frame fixing units 628, the annular frame 3 of the frame unit 19 is clamped from the outer circumferential side and the annular frame 3 is fixed.

Subsequently, the irradiation head 7 of the laser processing apparatus 13 is positioned above the substrate 1 in the state in which the substrate 1 is supported by the second support table 62. At this time, the orientation of the irradiation head 7 is set downward to cause the laser beam 70 emitted from the irradiation head 7 to be oriented in the −Z direction. In addition, focusing adjustment of the irradiation head 7 is executed to cause a focal point 700 of the laser beam 70 to be positioned inside the substrate 1.

Moreover, the position of the second support table 62 is adjusted by the horizontal movement mechanism and the rotation mechanism to cause the irradiation position of the laser beam 70 to be positioned to an end part on the −X direction side in one planned dividing line 100 in the substrate 1.

Then, the second support table 62 is moved in the −X direction by the horizontal movement mechanism while irradiation with the laser beam 70 from the irradiation head 7 is executed. Due to this, the irradiation head 7 moves in the +X direction relative to the substrate 1 supported by the second support table 62 and irradiation with the laser beam 70 from the irradiation head 7 is executed along the planned dividing line 100.

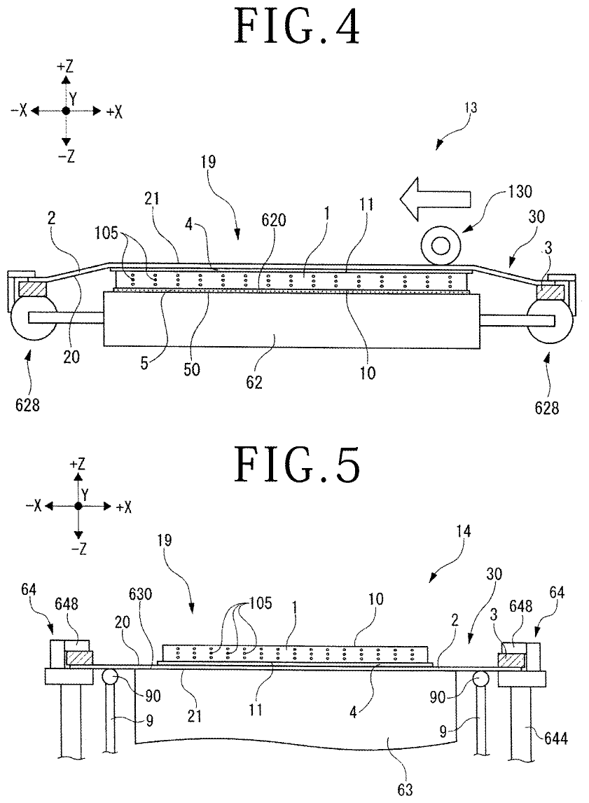

Thereby, a modified layer 105 is formed inside the substrate 1 as illustrated in FIG. 4. The modified layer 105 becomes the origin of dividing of the substrate 1 when the substrate 1 is divided in a chip interval expansion step to be described later.

Thereafter, the irradiation position of the laser beam 70 is positioned to another planned dividing line 100 parallel to the planned dividing line 100 already irradiated with the laser beam 70 by moving the second support table 62 in a Y-axis direction by the horizontal movement mechanism, and laser processing is executed on the planned dividing line 100 similarly. Moreover, the irradiation position of the laser beam 70 is positioned to one planned dividing line 100 that intersects the planned dividing line 100 already irradiated with the laser beam 70 by, rotating the second support table 62 by 90 degrees by the rotation mechanism, and similar laser processing is executed on this planned dividing line 100.

In this manner, finally, irradiation with the laser beam 70 is executed along all planned dividing lines 100 illustrated in FIG. 1 and the modified layers 105 are formed inside the substrate 1 along the respective planned dividing lines 100.

(Close Contact Step)

In this step, after the execution of the modified layer forming step and before execution of the chip interval expansion step to be described later, the expanding tape 2 is brought into close contact with the substrate 1 of the frame unit 19.

When the expanding tape 2 is brought into close contact with the substrate 1, in the state in which either one of the substrate 1 of the frame unit 19 and the expanding tape 2 is supported by the second support table 62 of the laser processing apparatus 13, a roller is rolled against the other. In the present embodiment, as illustrated in FIG. 4, a roller 130 included in the laser processing apparatus 13 is rolled against the expanding tape 2 in the state in which the substrate 1 is supported by the second support table 62.

The roller 130 is a cylindrical component that extends in the direction toward the far side of the plane of paper (Y-axis direction) and is configured to roll in the X-axis direction by a rolling mechanism that is not illustrated in the diagram similarly to the roller 120 of the expanding tape sticking apparatus 12 illustrated in FIG. 2.

Specifically, first, in the state in which the substrate 1 is supported by the second support table 62, the roller 130 is brought into contact with a part on the +X direction side in the contact surface 21 of the expanding tape 2 as illustrated in FIG. 4.

Then, the roller 130 is rolled in the −X direction by the rolling mechanism and thereby the roller 130 presses the expanding tape 2 against the substrate 1. Due to this, the expanding tape 2 gets close contact with the substrate 1.

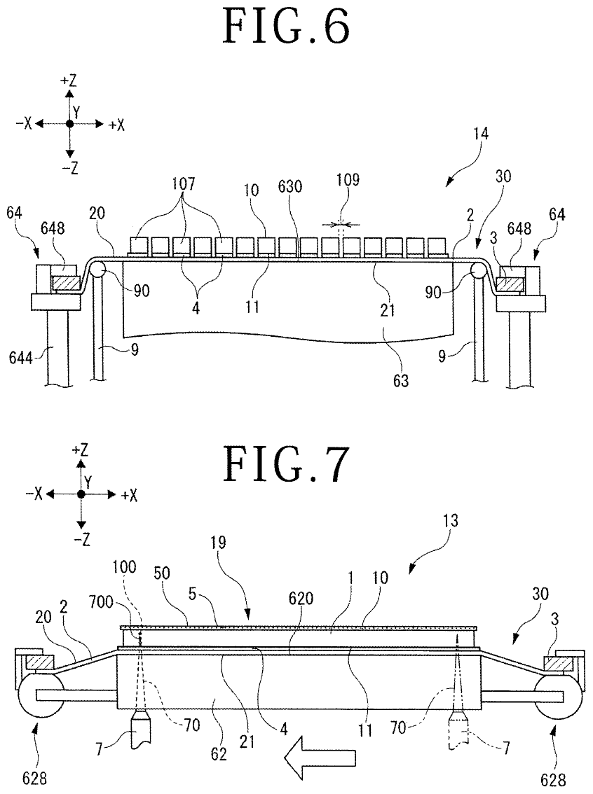

At this time, vibrations may occur in chips to be divided from the substrate 1 due to the rolling operation of the roller 130 and chips 107 like ones illustrated in FIG. 6 may be formed through dividing of part of the substrate 1 with the modified layers 105 being the origin.

In the close contact step, instead of rolling the roller 130 in the −X direction, the second support table 62 may be horizontally moved in the +X direction with the roller 130 fixed to an end part on the +X direction side in the contact surface 21. Also in this case, the roller 130 presses the expanding tape 2 against the substrate 1 and the expanding tape 2 gets close contact with the substrate 1.

(Chip Interval Expansion Step)

In this step, after the execution of the modified layer forming step and the close contact step, the expanding tape 2 is expanded by an expander 14 illustrated in FIG. 5 and FIG. 6 and the substrate is divided into the plural chips 107 with use of the modified layers 105 as the origin. In addition, an interval 109 formed between the plural chips 107 is widened.

The expander 14 includes a holding table 63. The holding table 63 includes a holding surface 630 for holding the frame unit 19. Furthermore, the expander 14 includes four frame holding units 64 that fix the annular frame 3 around the holding table 63, and two of these frame holding units 64 are illustrated in FIG. 5. The four frame holding units 64 are disposed at equal intervals on the same circumference, for example. The frame holding unit 64 includes a holding clamp 648 that clamps and fixes the annular frame 3 from the outer circumferential side and a shaft part 644 that supports the holding clamp 648.

Furthermore, the expander 14 includes four pushing-up components 9 with a cylindrical shape, and two of these pushing-up components 9 are illustrated in FIG. 5. The four pushing-up components 9 are disposed at equal intervals on the same circumference inside the circle formed by the four frame holding units 64, for example.

The pushing-up components 9 and the holding table 63 are connected to a raising-lowering mechanism that is not illustrated in the diagram and risen and lowered in a Z-axis direction by this raising-lowering mechanism. Spherical roller components 90 are rotatably attached to the upper ends of the pushing-up components 9. The roller components 90 get contact with the contact surface 21 of the expanding tape 2 and alleviate friction when the pushing-up components 9 push up the expanding tape 2.

When the expanding tape 2 is expanded, first, the frame unit 19 is removed from the laser processing apparatus 13 (see FIG. 4) and the protective sheet 5 stuck to the front surface 10 of the substrate 1 is separated from the substrate 1. Then, as illustrated in FIG. 5, the substrate 1 of the frame unit 19 is placed over the holding surface 630 of the holding table 63 in the state in which the front surface 10 of the substrate 1 is oriented upward. Moreover, the annular frame 3 of the frame unit 19 is clamped and fixed by the holding clamps 648 of the four frame holding units 64.

Due to this, as illustrated in FIG. 5, the roller components 90 of the pushing-up components 9 get contact with the contact surface 21 of the expanding tape 2 in the frame unit 19. Then, in this state, the pushing-up components 9 and the holding table 63 are raised in the +Z direction. Thereby, as illustrated in FIG. 6, the roller components 90 push up the expanding tape 2 and extend the expanding tape 2 in the surface direction (X-axis direction and Y-axis direction).

In association with such expansion of the expanding tape 2 in the surface direction, a radial tensile force is applied to the substrate 1 stuck to the expanding tape 2. As a result, the substrate 1 is divided with the modified layers 105 being the origin and the plural chips 107 are formed, so that the interval 109 is formed between the plural chips 107. Furthermore, the formed interval 109 between the respective chips 107 is widened to a predetermined size.

Moreover, in the chip interval expansion step, the glue layer 4 stacked on the expanding tape 2 is also divided along the modified layers 105 when the expanding tape 2 is expanded in the above-described manner. That is, in the chip interval expansion step, the substrate 1 and the glue layer 4 are integrally divided along the modified layers 105 due to the expansion of the expanding tape 2.

As above, in the present embodiment, after the execution of the modified layer forming step and before the execution of the chip interval expansion step, the expanding tape 2 is brought into close contact with the substrate 1 in the close contact step. Thus, for example, even when the degree of bonding between the substrate 1 and the expanding tape 2 has lowered due to the elapse of time, the degree of bonding between both can be restored by the execution of the close contact step. Therefore, when the expanding tape 2 is expanded in the chip interval expansion step, the substrate 1 is pulled together with the expanding tape 2 and it is possible to favorably divide the substrate 1 with use of the modified layers 105 as the origin and favorably form the plural chips 107 and to favorably widen the interval 109 between the plural chips 107.

Furthermore, by the close contact step, the roller 130 rolls while applying a pressure to the substrate. This provides also an effect that, because of minute motion of the chips 107 due to the pressing by the roller 130, cracks extend with the modified layers 105 being the origin and the substrate 1 can be favorably divided into the plural chips 107 and the interval 109 between the chips 107 favorably widens in the chip interval expansion step.

Moreover, in the present embodiment, in the close contact step, the roller 130 is rolled against the expanding tape 2 in the state in which the substrate 1 is supported by the second support table 62. Therefore, the expanding tape 2 can be easily brought into close contact with the substrate 1. The close contact step may be executed in the state in which the substrate 1 is supported by not the second support table 62 of the laser processing apparatus 13 but the holding table 63 of the expander 14.

Furthermore, the glue layer 4 is stacked on the expanding tape 2 stuck to the substrate 1 and the glue layer 4 is divided along the modified layers 105 together with the substrate 1 in the chip interval expansion step. The respective glue layers 4 resulting from the dividing play a role as an adhesive when the chip 107 is stacked.

In the chip interval expansion step, after the interval 109 between the respective chips 107 is widened to a predetermined size as illustrated in FIG. 6, the respective chips 107 may be sucked and held from the side of the expanding tape 2 by the holding surface 630 of the holding table 63 through connecting the holding surface 630 to a suction source (not illustrated). This can keep the interval 109 between the respective chips 107.

### Second Embodiment

The present embodiment is different from the first embodiment in that the substrate 1 is irradiated with the laser beam 70 through the second support table 62 in the modified layer forming step. A dividing method of a substrate according to the present embodiment will be described below.

(Expanding Tape Sticking Step)

Also in the present embodiment, first, as illustrated in FIG. 2, the frame unit 19 is formed by sticking the expanding tape 2 to the back surface 11 of the substrate 1 similarly to the expanding tape sticking step of the first embodiment.

(Modified Layer Forming Step)

In this step, after the execution of the expanding tape sticking step, as illustrated in FIG. 7, laser processing on the planned dividing lines 100 of the substrate 1 is executed by the above-described laser processing apparatus 13.

The laser processing apparatus 13 includes the second support table 62 and the frame fixing units 628 as described above and they are horizontally moved or rotationally moved by the horizontal movement mechanism and the rotation mechanism that are not illustrated in the diagram. However, in the present embodiment, the second support table 62 is a semitransparent body or transparent body (for example, glass) that is a material through which the laser beam 70 emitted from the irradiation head 7 is transmitted.

In the present embodiment, when the laser processing on the planned dividing lines 100 of the substrate 1 is executed by the laser processing apparatus 13, first, as illustrated in FIG. 7, the contact surface 21 of the expanding tape 2 in the frame unit 19 is oriented downward and the substrate 1 of the frame unit 19 is placed over the support surface 620 of the second support table 62 with the interposition of the expanding tape 2. Due to this, the second support table 62 supports the expanding tape 2 (that is, the second support table 62 supports the substrate 1 through the expanding tape 2).

At this time, the expanding tape 2 may be sucked and held by the support surface 620 by actuating the suction source that is connected to the second support table 62 and is not illustrated in the diagram and transmitting a suction force to the support surface 620 of the second support table 62.

Furthermore, by the frame fixing units 628, the annular frame 3 of the frame unit 19 is clamped from the outer circumferential side and the annular frame 3 is fixed.

Subsequently, the irradiation head 7 is positioned below the second support table 62 in the state in which the substrate 1 is supported by the second support table 62. Moreover, as illustrated in FIG. 7, the orientation of the irradiation head 7 is set upward to cause the laser beam 70 emitted from the irradiation head 7 to be oriented in the +Z direction. In addition, focusing adjustment of the irradiation head 7 is executed to irradiate the substrate 1 with the laser beam 70 transmitted through the second support table 62 and cause the focal point 700 thereof to be positioned inside the substrate 1.

Moreover, the position of the second support table 62 is adjusted by the horizontal movement mechanism and the rotation mechanism to cause the irradiation position of the laser beam 70 to be positioned to an end part on the −X direction side in one planned dividing line 100 in the substrate 1.

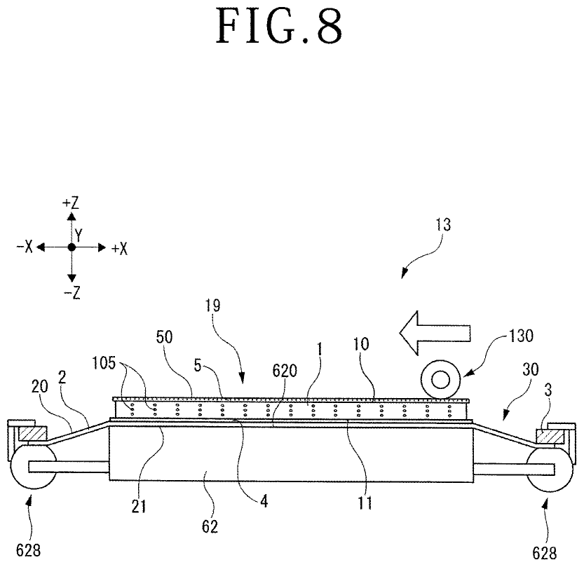

Then, the second support table 62 and the frame fixing units 628 are moved in the −X direction by the above-described horizontal movement mechanism that is not illustrated in the diagram while irradiation with the laser beam 70 from the irradiation head 7 is executed. Due to this, the irradiation head 7 moves in the +X direction relative to the substrate 1 supported by the second support table 62 and irradiation with the laser beam 70 from the irradiation head 7 is executed along the planned dividing line 100. Thereby, as illustrated in FIG. 8, the modified layer 105 is formed inside the substrate 1.

Thereafter, similarly to the first embodiment, irradiation with the laser beam 70 is executed while the second support table 62 is moved by the horizontal movement mechanism and the rotation mechanism and thereby the modified layers 105 are formed inside the substrate 1 along all planned dividing lines 100.

The protective sheet 5 does not have to be stuck to the front surface 10 of the substrate 1 at the time of the execution of the modified layer forming step in the second embodiment.

(Close Contact Step)

In this step, similarly to the first embodiment, after the execution of the modified layer forming step and before the execution of the chip interval expansion step, the expanding tape 2 is brought into close contact with the substrate 1 of the frame unit 19. When the above-described modified layer forming step has been executed in the state in which the protective sheet 5 is not stuck to the front surface 10 of the substrate 1, the protective sheet 5 is stuck to the front surface 10 of the substrate 1 at the time of start of the close contact step.

When the expanding tape 2 is brought into close contact with the substrate 1, in the present embodiment, as illustrated in FIG. 8, the roller 130 is rolled against the substrate 1 in the state in which the expanding tape 2 is supported by the second support table 62.

Specifically, first, the roller 130 is brought into contact with an end part on the +X direction side in a front surface 50 of the protective sheet 5 stuck to the substrate 1 in the state in which the expanding tape 2 is supported by the second support table 62.

Then, the expanding tape 2 is pressed against the substrate 1 by rolling the roller 130 in the −X direction by the rolling mechanism that is not illustrated in the diagram, and the expanding tape 2 gets close contact with the substrate 1.

Similarly to the close contact step in the first embodiment, vibrations may be transmitted to the inside of the substrate 1 due to the rolling operation of the roller 130 and the chips 107 like the ones illustrated in FIG. 6 may be formed through dividing of part of the substrate 1 with the modified layers 105 being the origin.

In the close contact step, instead of rolling the roller 130 in the −X direction, the second support table 62 may be horizontally moved in the +X direction with the roller 130 fixed to an end part on the +X direction side in the contact surface 21.

(Chip Interval Expansion Step)

In this step, similarly to the chip interval expansion step in the first embodiment, by the expander 14 illustrated in FIG. 5 and FIG. 6, the expanding tape 2 is expanded to divide the substrate 1 into the plural chips 107 with use of the modified layers 105 as the origin and widen the interval 109 formed between the plural chips 107. That is, through the expansion of the expanding tape 2, the substrate 1 is divided with use of the modified layers 105 as the origin to form the plural chips 107. In addition, the formed interval 109 between the respective chips 107 is widened to a predetermined size.

Furthermore, similarly to the chip interval expansion step in the first embodiment, the glue layer 4 stacked on the expanding tape 2 is divided along the modified layers 105 when the expanding tape 2 is expanded. That is, the substrate 1 and the glue layer 4 are integrally divided due to the expansion of the expanding tape 2.

As above, also in the second embodiment, the expanding tape 2 is brought into close contact with the substrate 1 in the close contact step after the execution of the modified layer forming step and before the execution of the chip interval expansion step. Thus, when the expanding tape 2 is expanded in the chip interval expansion step, it is possible to favorably divide the substrate 1 with use of the modified layers 105 as the origin and favorably form the plural chips 107 and to favorably widen the interval 109 between the plural chips 107.

Furthermore, in the second embodiment, in the close contact step, the roller 130 is rolled against the substrate 1 in the state in which the expanding tape 2 is supported by the second support table 62. Therefore, the expanding tape 2 can be easily brought into close contact with the substrate 1 similarly to the close contact step in the first embodiment.

In the first and second embodiments, the close contact step is executed in the laser processing apparatus 13 by using the second support table 62 and the roller 130. Regarding this, the close contact step may be executed in the expander 14 by using a support table and a roller for the close contact step that are not illustrated in the diagram. Alternatively, the close contact step may be executed by an independent close contact apparatus that is separate apparatus from the laser processing apparatus 13 and the expander 14 and includes a support table and a roller and is not illustrated in the diagram.

Furthermore, in the chip interval expansion step, the expanding tape 2 may be pushed up from the lower side and be expanded by supporting the contact surface 21 of the expanding tape 2 by a circular columnar expanding drum that is not illustrated in the diagram and raising this expanding drum instead of expanding the expanding tape 2 by the pushing-up components 9.

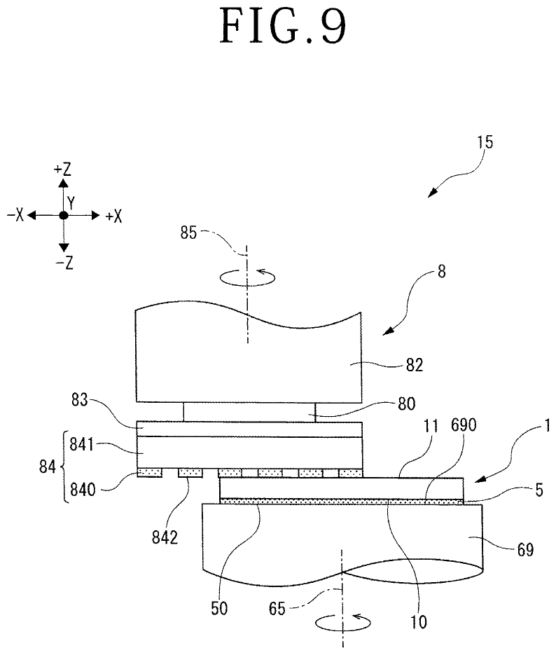

Moreover, the dividing methods of a substrate illustrated in the first and second embodiments may include a grinding step executed before execution of the expanding tape sticking step. This grinding step is executed by a grinding apparatus 15 illustrated in FIG. 9. The grinding apparatus 15 includes a grinding mechanism 8 and a chuck table 69. In the grinding step, the back surface 11 of the substrate 1 held by the chuck table 69 is ground to a finished thickness by the grinding mechanism 8.

The grinding mechanism 8 includes a spindle 80, a spindle motor 82 that rotates the spindle 80 around a rotation axis 85 in the Z-axis direction, a mount 83 disposed at the lower end of the spindle 80, and a grinding wheel 84 mounted on the mount 83. The grinding wheel 84 includes a wheel base 841 and plural grinding abrasive stones 840 that are annularly arranged on the lower surface of the wheel base 841 and have a substantially rectangular parallelepiped shape. The grinding abrasive stones 840 are finishing grinding abrasive stones, for example.

The grinding mechanism 8 is connected to a raising-lowering mechanism that is not illustrated in the diagram, and can rise and lower in the Z-axis direction by this raising-lowering mechanism. The upper surface of the chuck table 69 is a holding surface 690 for holding the substrate 1. The chuck table 69 is connected to a rotation mechanism that is not illustrated in the diagram, and can rotate around a rotation axis 65 that passes through the center of the holding surface 690 and is in the Z-axis direction.

In grinding of the back surface 11 of the substrate 1 by the grinding mechanism 8, the substrate 1 is placed on the holding surface 690 of the chuck table 69 with the protective sheet 5 stuck to the front surface 10 thereof oriented downward. Then, the front surface 50 of the protective sheet 5 is sucked by a suction source that is connected to the holding surface 690 and is not illustrated in the diagram. This causes the chuck table 69 to suck and hold the substrate 1 with the interposition of the protective sheet 5 by the holding surface 690.

Subsequently, the chuck table 69 is rotated around the rotation axis 65 in the Z-axis direction by the rotation mechanism that is not illustrated in the diagram, and the substrate 1 held by the chuck table 69 is rotated. Furthermore, the grinding abrasive stones 840 are rotated around the rotation axis 85 by the spindle motor 82. In this state, the grinding abrasive stones 840 are lowered in the −Z direction by the raising-lowering mechanism that is not illustrated in the diagram. Thereby, lower surfaces 842 of the grinding abrasive stones 840 get contact with the back surface 11 of the substrate 1 and grind the back surface 11. In the grinding of the substrate 1 by the grinding mechanism 8, for example, thickness measurement of the substrate 1 by a thickness measurement mechanism that is not illustrated in the diagram is executed and the grinding is ended when the back surface 11 of the substrate 1 has been ground to the finished thickness.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A dividing method of a substrate for dividing the substrate along planned dividing lines, the dividing method comprising:
an expanding tape sticking step of sticking an expanding tape to a back surface of the substrate;
a modified layer forming step of executing irradiation with a laser beam with a wavelength having transmissibility with respect to the substrate along the planned dividing lines in a state in which a focal point is positioned inside the substrate, to form modified layers that become an origin of dividing inside the substrate, after execution of the expanding tape sticking step;
a close contact step of bringing the expanding tape into close contact with the substrate after execution of the modified layer forming step; and
a chip interval expansion step of expanding the expanding tape to divide the substrate into a plurality of chips with use of the modified layers as the origins and widen an interval formed between the plurality of chips after execution of the close contact step.

2. The dividing method of a substrate according to claim 1, wherein,
in the close contact step, in a state in which either one of the substrate and the expanding tape is supported by a support table, a roller is rolled against another.

3. The dividing method of a substrate according to claim 1, wherein
a glue layer is stacked on the expanding tape, and
the glue layer is divided along the modified layers in the chip interval expansion step.
